(19) United States
(12) Patent Application Publication
(10) Pub. No.: US 2024/0038813 A1
(43) Pub. Date: Feb. 1, 2024

(54) SEMICONDUCTOR DEVICE AND ELECTRONIC APPARATUS

(71) Applicant: LAPIS SEMICONDUCTOR CO., LTD., KANAGAWA (JP)

(72) Inventor: ATSUSHI YABATA, KANAGAWA (JP)

(21) Appl. No.: 18/227,705

(22) Filed: Jul. 28, 2023

(30) Foreign Application Priority Data
Jul. 29, 2022 (JP) 2022-122182

(51) Int. Cl. H01L 27/146; H04N 25/78

(52) U.S. Cl. CPC H01L 27/14636; H01L 27/14643; H01L 27/14623; H04N 25/78

(57) ABSTRACT

A pixel 10 is provided with a lower metal electrode 41, an upper metal electrode 43, a capacitor insulation layer 42, contacts 44 and 45 and a contact 46. The lower metal electrode 41, upper metal electrode 43 and capacitor insulation layer 42 are formed on a semiconductor substrate 21, are clear of a region in which a photodiode 11 is formed, and are formed at a region in which a reading circuit 13 is formed. At least the contacts 44 and 45 electrically connect the lower metal electrode 41 with a metal wire 40, and at least the contact 46 electrically connects the upper metal electrode 43 with the metal wire 40.

### CROSS-REFERENCE TO RELATED APPLICATION

This application is based on and claims priority under 35 USC 119 from Japanese Patent Application No. 2022-122182 filed on Jul. 29, 2022, the disclosure of which is incorporated by reference herein.

### BACKGROUND

### Technical Field

The present disclosure relates to a semiconductor device and an electronic apparatus.

### Related Art

In an optical sensor component, to prevent malfunction of a transistor in an analog circuit region, a structure in which a light shield metal is formed at an uppermost layer is employed (see Japanese Patent Application Laid-Open (JP-A) No. 2006-294963 and Japanese Patent No. 6,986,857). This structure allows light to enter from a top face side, the light is received at a photodiode and photoelectrically converted, and electronic signals are processed. For processing the electronic signals, a transistor or the like is disposed in each pixel of the sensor and structures an analog circuit for reading. However, if light is incident on the transistor region, the transistor malfunctions. Accordingly, the light shield metal is formed so as to prevent light entering the transistor region.

A capacitive element is required for accumulation of electronic signals from a photodiode or for a CDS (correlated double sampling) circuit or the like. Accordingly, a metal-oxide-semiconductor (MOS) capacitor, metal-insulator-metal (MIM) capacitor or the like is embedded in each pixel. However, these components require areas on silicon and areas for wiring regions. As a result, the pixel size is enlarged.

### SUMMARY

According to an aspect of the present disclosure, a semiconductor device is provided that includes: a light-receiving element formed on a substrate; a reading circuit that reads charges generated in accordance with light received at the light-receiving element; a first light shield layer and a second light shield layer which are formed so as to cover over the reading circuit; and a capacitor insulation layer formed at at least a portion of a region between the first light shield layer and the second light shield layer.

### BRIEF DESCRIPTION OF THE DRAWINGS

An exemplary embodiment of the present disclosure will be described in detail based on the following figures, wherein:

FIG. 1 is a plan view showing a cutout of a single pixel of a solid state imaging element formed at a semiconductor device according to the exemplary embodiment.

FIG. 2 is a sectional diagram showing a sectional example along line A-B in FIG. 1.

FIG. 3 is a sectional diagram showing a magnification of a section of an MIM capacitor.

FIG. 4 is a sectional diagram showing a sectional example along line A-B in FIG. 1.

FIG. 5 is a sectional diagram showing a magnification of a section of an MIM capacitor.

FIG. 6 is a plan view showing a cutout of four pixels of the solid state imaging element formed at the semiconductor device according to the present exemplary embodiment.

FIG. 7 is a sectional diagram showing a sectional example along line X-Y in FIG. 6.

FIG. 8 is a structural diagram showing a functional structure example of an electronic apparatus equipped with the solid state imaging element according to the present exemplary embodiment.

FIG. 9 is a sectional diagram showing a comparative example of a section along line A-B in FIG. 1.

### DETAILED DESCRIPTION

Below, an example of an embodiment of the present disclosure is described with reference to the drawings. In the drawings, the same reference symbols are assigned to structural elements and portions that are the same or equivalent. Proportional dimensions in the drawings may be exaggerated to aid understanding and may be different from actual proportions.

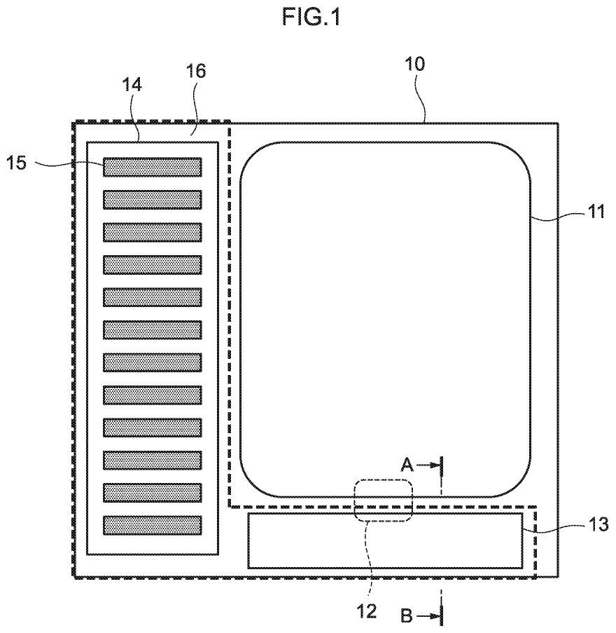

FIG. 1 is a plan view showing a cutout of a single pixel of a solid state imaging element formed at a semiconductor device according to the present exemplary embodiment. A pixel 10 that is depicted in FIG. 1 is arrayed in two dimensions to form an imaging area of the solid state imaging element.

The pixel 10 includes a photodiode 11, a floating diffusion (FD) portion 12 for receiving transfers of charge from the photodiode 11, a reading circuit 13 that reads charges generated by the photodiode 11, and a polysilicon 14 at which a MOS capacitor 15 is formed. Charges accumulated in the MOS capacitor 15 are read out by a reading circuit formed at a periphery of the imaging area, and required signal processing is performed by a signal processing circuit that is similarly formed at the periphery of the imaging area. The MOS capacitor 15 that is employed may be a planar-type or trench-type capacitor.

In a solid state imaging element on which light is incident from an upper portion, a metal light shield layer 16 (the region surrounded by broken lines in FIG. 1) is formed at regions of the pixel 10 excluding a region in which the photodiode 11 is formed, in order to prevent malfunctions due to light being incident on the reading circuit 13 and the polysilicon 14. The metal light shield layer 16 is formed of a high reflectivity material such as, for example, tungsten (W) molybdenum (Mo), tantalum (Ta), platinum (Pt), copper (Cu), TiW, TiN, WN or the like.

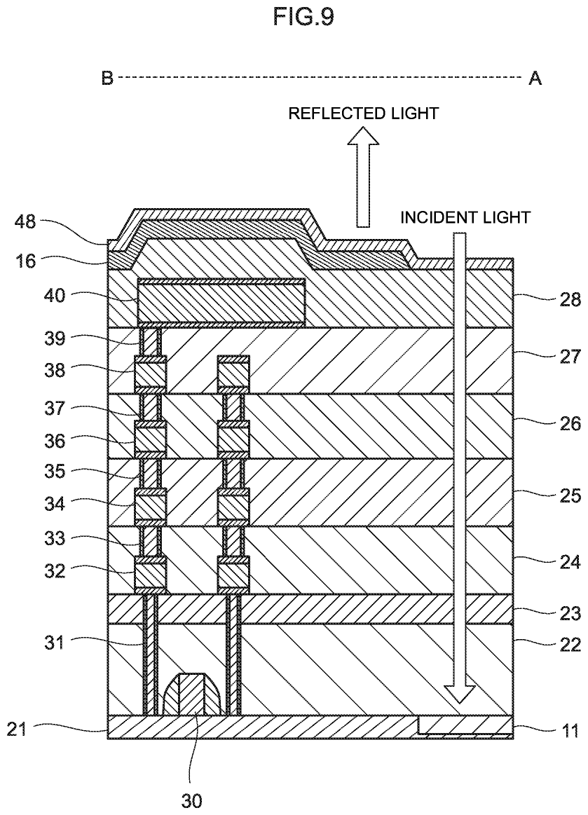

Now, a comparative example of the exemplary embodiment is described. FIG. 9 is a sectional diagram showing a comparative example of a section along line A-B in FIG. 1. In the pixel 10, the photodiode 11 and a transistor 30 are formed on a semiconductor substrate 21. The transistor 30 is formed in order to transfer charges generated by the photodiode 11 to the reading circuit 13. In the descriptions below, a direction in which incident light is incident is from up to down, and a direction of reflected light is from down to up.

Metal wires 32, 34, 36, 38 and 40, for driving the transistor 30, and contacts 31, 33, 35, 37 and 39, for connecting the metal wires, are formed at the pixel 10. The metal wire 32 is formed on interlayer insulation layers 22 and 23, and the metal wires 34, 36, 38 and 40 are formed on, respectively, interlayer insulation layers 24, 25, 26 and 27. An interlayer insulation layer 28 is formed on the interlayer insulation layer 27 and the metal wire 40. The interlayer insulation layers 22, 23, 24, 25, 26, 27 and 28 employ silicon nitride (SiN), silicon oxynitride (SiON) or the like. The metal light shield layer 16 is formed on regions of the interlayer insulation layer 28 excluding a region in which the photodiode 11 is formed. A nitride layer 48 is formed on the metal light shield layer 16 and the interlayer insulation layer 28. The nitride layer 48 is, for example, a SiN layer, a SiON layer or the like.

When the sensitivity of a solid state imaging element is to be raised, it is usual to increase the area of the photodiode 11. When the area of the photodiode 11 is increased, amounts of charge generated in accordance with received light increase. Therefore, the capacitance of a capacitor for accumulating charge must be increased.

MOS capacitors include planar-type capacitors and trench-type capacitors. When a MOS capacitor is a planar-type capacitor, because an electrode is formed at a top face, the capacitance may be increased by increasing an area in plan view of the capacitor. However, an increase in area in plan view leads to an increase in pixel size, and an increase in pixel size leads to a reduction in the number of pixels, and therefore a decrease in resolution. When a MOS capacitor is a trench-type capacitor, the capacitance may be increased by making the trench deeper, provided the area of an electrode can be easily increased. However, increasing the depth of a trench raises the difficulty of processing steps, leading to a reduction in fabrication yield due to physical flaws.

In the pixel 10 according to the present exemplary embodiment, an MIM (metal-insulator-metal) capacitor employing the metal light shield layer 16 is formed inside the pixel 10. When the metal light shield layer 16 is employed at an MIM capacitor, the capacitor may be formed at regions apart from the region in which the photodiode 11 is formed. That is, the capacitance of the capacitor may be increased without increasing the size of the pixel 10 according to the present exemplary embodiment.

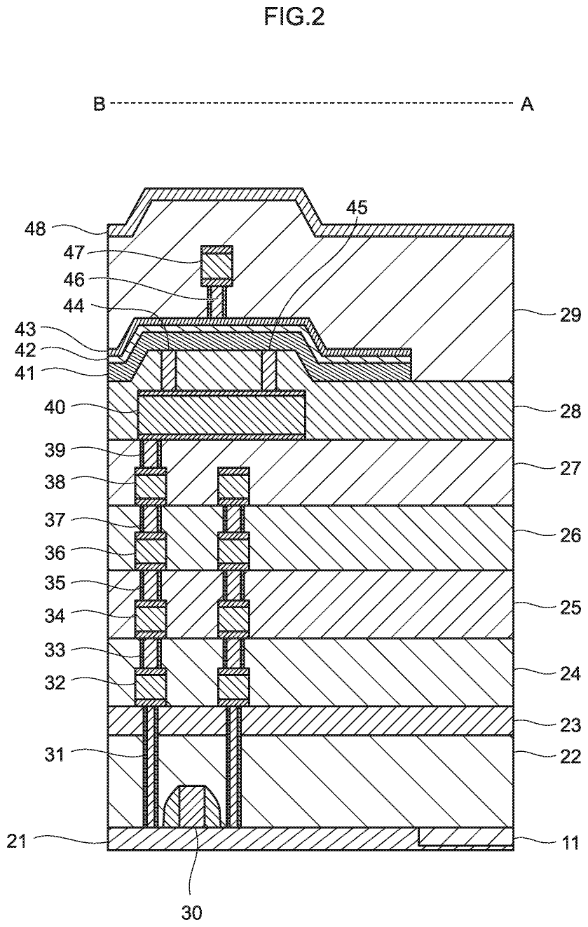

FIG. 2 is a sectional diagram showing a sectional example along line A-B in FIG. 1. In the pixel 10, the photodiode 11 and the transistor 30 are formed on the semiconductor substrate 21. In the descriptions below, the direction in which incident light is incident is from up to down, and the direction of reflected light is from down to up.

In the pixel 10, similarly to the pixel 10 that is illustrated in FIG. 9, the metal wires 32, 34, 36, 38 and 40 for driving the transistor 30 and the contacts 31, 33, 35, 37 and 39 for connecting the metal wires are formed. The metal wire 32 is formed on the interlayer insulation layers 22 and 23, and the metal wires 34, 36, 38 and 40 are formed on, respectively, the interlayer insulation layers 24, 25, 26 and 27. The interlayer insulation layers 22, 23, 24, 25, 26, 27 and 28 employ silicon nitride (SiN), silicon oxynitride (SiON) or the like.

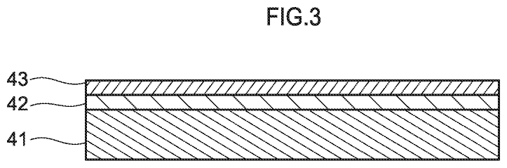

A lower metal electrode 41, a capacitor insulation layer 42 and an upper metal electrode 43 are formed on the interlayer insulation layer 28. An MIM capacitor is formed by the lower metal electrode 41, the capacitor insulation layer 42 and the upper metal electrode 43. FIG. 3 is a sectional diagram showing a magnification of a section of the MIM capacitor formed by the lower metal electrode 41, the capacitor insulation layer 42 and the upper metal electrode 43.

The lower metal electrode 41 has the function of a metal light shield layer that is for preventing malfunctions due to light being incident on the reading circuit 13 and the polysilicon 14. Contacts 44 and 45 for supplying a potential of the lower metal electrode 41 are formed between the lower metal electrode 41 and the metal wire 40 and are in contact with the lower metal electrode 41 and metal wire 40.

A metal wire 47, for reading a charge accumulated by the MIM capacitor, is formed on the upper metal electrode 43. A contact 46 for supplying a potential of the upper metal electrode 43 is formed between the upper metal electrode 43 and the metal wire 47 and is in contact with the upper metal electrode 43 and metal wire 47.

The metal wire 40 is an example of a first metal wire of the present disclosure, and the metal wire 47 is an example of a second metal wire of the present disclosure. The contacts 44 and 45 are an example of a first contact of the present disclosure, and the contact 46 is an example of a second contact of the present disclosure.

The MIM capacitor may be formed at the pixel 10 according to the present exemplary embodiment in a region excluding the region in which the photodiode 11 is formed. Thus, in the pixel 10 according to the present exemplary embodiment, because the MIM capacitor is formed at regions apart from the region in which the photodiode 11 is formed, the capacitance of the capacitor may be increased without increasing the pixel size.

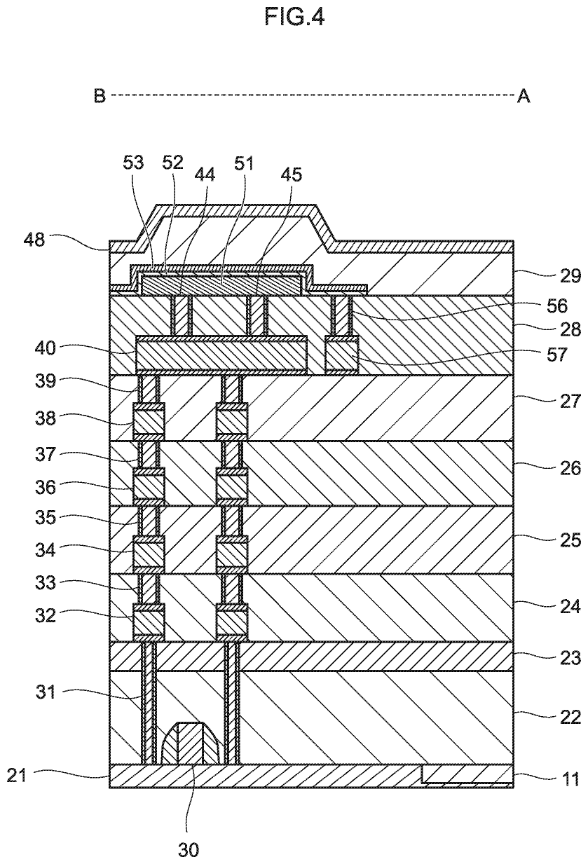

A different variant example of the pixel 10 according to the present exemplary embodiment is illustrated. FIG. 4 is a sectional diagram showing a sectional example along line A-B in FIG. 1. In the pixel 10, the photodiode 11 and the transistor 30 are formed on the semiconductor substrate 21. In the descriptions below, the direction in which incident light is incident is from up to down, and the direction of reflected light is from down to up.

In the pixel 10, similarly to the pixel 10 that is illustrated in FIG. 9, the metal wires 32, 34, 36, 38 and 40 for driving the transistor 30 and the contacts 31, 33, 35, 37 and 39 for connecting the metal wires are formed. The metal wire 32 is formed on the interlayer insulation layers 22 and 23, and the metal wires 34, 36, 38 and 40 are formed on, respectively, the interlayer insulation layers 24, 25, 26 and 27. The interlayer insulation layers 22, 23, 24, 25, 26, 27 and 28 employ silicon nitride (SiN), silicon oxynitride (SiON) or the like.

A lower metal electrode 51, a capacitor insulation layer 52 and an upper metal electrode 53 are formed on the interlayer insulation layer 28. An MIM capacitor is formed by the lower metal electrode 51, the capacitor insulation layer 52 and the upper metal electrode 53.

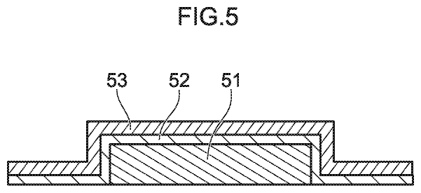

FIG. 5 is a sectional diagram showing a magnification of a section of the MIM capacitor formed by the lower metal electrode 51, the capacitor insulation layer 52 and the upper metal electrode 53. In the pixel 10 with the sectional structure shown in FIG. 4, side wall portions of the lower metal electrode 51 may also be utilized as capacitance of the MIM capacitor.

The upper metal electrode 53 has the function of a metal light shield layer for preventing malfunctions due to light being incident on the reading circuit 13 and the polysilicon 14. The contacts 44 and 45, for supplying a potential of the lower metal electrode 51, are formed between the lower metal electrode 51 and the metal wire 40 and are in contact with the lower metal electrode 51 and metal wire 40.

A metal wire 57, for reading a charge accumulated by the MIM capacitor, is formed on the interlayer insulation layer 27. A contact 56 for supplying a potential of the upper metal electrode 53 is formed between the upper metal electrode 53 and the metal wire 57 and is in contact with the upper metal electrode 53 and metal wire 57.

The metal wire 40 is an example of the first metal wire of the present disclosure, and the metal wire 57 is an example of the second metal wire of the present disclosure. The contacts 44 and 45 are an example of the first contact of the present disclosure, and the contact 56 is an example of the second contact of the present disclosure.

In the pixel 10 with the sectional structure shown in FIG. 4, in contrast to the pixel 10 with the sectional structure shown in FIG. 2, the metal wire 40 and the metal wire 57 are formed at the same layer. Therefore, there is no need for a contact and a metal wire to be formed on the upper metal electrode.

MIM capacitors may be separated into pixel units by the pixel 10 being formed as shown in FIG. 2 or FIG. 4.

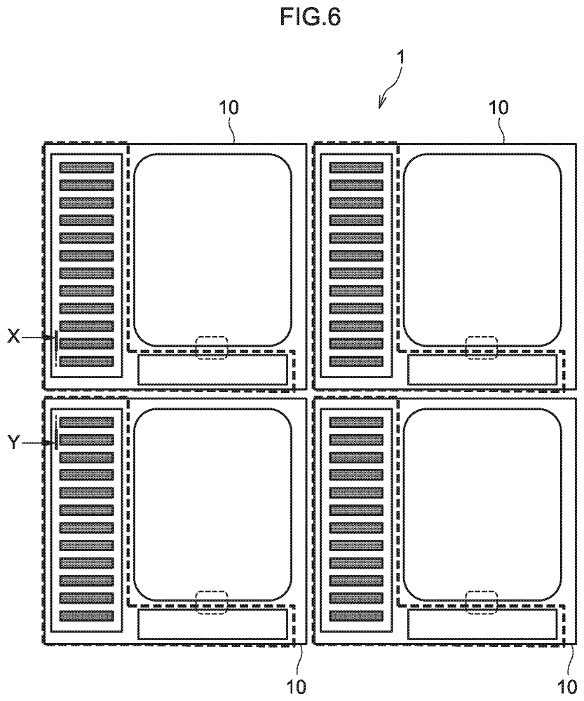

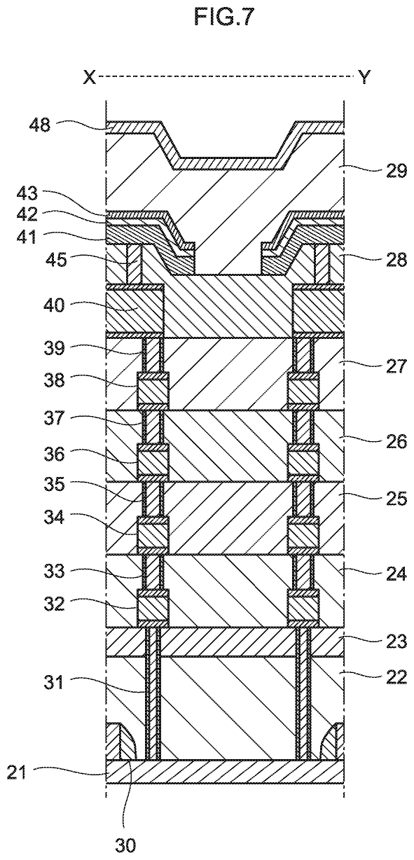

FIG. 6 is a plan view showing a cutout of four pixels of the solid state imaging element formed at the semiconductor device according to the present exemplary embodiment. FIG. 7 is a sectional diagram showing a section example along line X-Y in FIG. 6. The lower metal electrode 41 or upper metal electrode 43, which is formed to serve as a metal light shield layer, is formed to be separated into pixel units. Thus, in the pixel 10 according to the present exemplary embodiment, the MIM capacitors may be divided between pixel units.

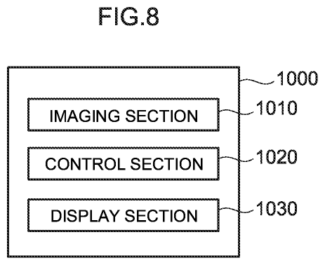

Now, a structural example of an electronic apparatus equipped with the solid state imaging element according to the present exemplary embodiment is described. FIG. 8 is a structural diagram showing a functional structure example of the electronic apparatus equipped with the solid state imaging element according to the present exemplary embodiment.

An electronic apparatus 1000 illustrated in FIG. 8 is provided with an imaging section 1010, a control section 1020 and a display section 1030. The electronic apparatus 1000 is an apparatus that is equipped with an object imaging function and an information display function, such as, for example, a portable telephone, a personal computer, a portable information terminal, a digital still camera, a digital video camera, a smart glass device, a video game machine or the like.

The imaging section 1010 includes a lens, a solid state imaging element and a signal processing circuit. The lens collects incident light from an object and focuses the incident light on an imaging surface of the solid state imaging element. The solid state imaging element converts light amounts of the incident light passing through the lens to electronic signals at pixel units. The signal processing circuit performs signal processing on the electronic signals generated by the solid state imaging element. The solid state imaging element employed in the imaging section 1010 is the solid state imaging element according to the exemplary embodiment described above.

The control section 1020 is an example of a processing device of the present disclosure, and controls operations of the electronic apparatus 1000. The control section 1020 includes a central processing unit (CPU), read-only memory (ROM) and random access memory (RAM). The control section 1020 controls all or some of operations of the electronic apparatus 1000, by the CPU reading and executing various programs recorded at the ROM, the RAM, a storage device that is not shown in the drawings or the like.

The display section 1030 is provided at a top face of the electronic apparatus 1000 and may be, for example a display apparatus such as, for example, a liquid crystal display, an organic electroluminescence (EL) display or the like. Under the control of the control section 1020, the display section 1030 displays control screens of the electronic apparatus 1000, and may display captured images acquired by the above-described imaging section 1010 and so forth.

Because the electronic apparatus 1000 is equipped with the solid state imaging device according to the exemplary embodiment described above, sensitivity at times of image capture by the imaging section 1010 may be raised and, because an increase in size of the individual pixels is suppressed, a decrease in resolution of the captured images captured by the imaging section 1010 may be suppressed.

Hereabove, an exemplary embodiment of the present disclosure has been described in detail with reference to the attached drawings, but the technical scope of the present disclosure is not limited to this example. It will be clear to the practitioner having ordinary skill in the field of art to which the present disclosure belongs that numerous modifications and improvements are possible within the scope of the technical gist recited in the attached claims, and it should be understood that these modifications and improvements are to be encompassed by the technical scope of the disclosure.

An object of the present disclosure is to provide a semiconductor device that may increase capacitance of a capacitive element compared to related art, without increasing pixel size, and an electronic apparatus equipped with the semiconductor device.

According to an aspect of the present disclosure, a semiconductor device is provided that includes: a light-receiving element formed on a substrate; a reading circuit that reads charges generated in accordance with light received at the light-receiving element; a first light shield layer and a second light shield layer which are formed so as to cover over the reading circuit; and a capacitor insulation layer formed at at least a portion of a region between the first light shield layer and the second light shield layer.

According to another aspect of the present disclosure, an electronic device is provided that includes: the semiconductor device; and a processing device that performs processing on charges read from the semiconductor device.

According to the present disclosure, a semiconductor device that may increase capacitance of a capacitive element compared to related art, without increasing pixel size, and an electronic apparatus equipped with the semiconductor device may be provided.

What is claimed is:

1. A semiconductor device comprising:
a light-receiving element formed on a substrate;
a reading circuit that reads charges generated in accordance with light received at the light-receiving element;
a first light shield layer and a second light shield layer which are formed so as to cover over the reading circuit; and
a capacitor insulation layer formed at at least a portion of a region between the first light shield layer and the second light shield layer.

2. The semiconductor device according to claim 1, further comprising:
a first metal wire and a second metal wire, which are formed on the reading circuit;
at least one first contact that electrically contacts the first light shield layer and the first metal wire; and
at least one second contact that electrically contacts the second light shield layer and the second metal wire.

3. The semiconductor device according to claim 2, wherein the second metal wire is formed at a different layer from the first metal wire.

4. The semiconductor device according to claim 2, wherein the second metal wire is formed at a same layer as the first metal wire.

5. The semiconductor device according to claim 1, further comprising pixels that are each structured by the light-receiving element and the reading circuit, the first light shield layer, the capacitor insulation layer and the second light shield layer being electrically separated into pixel units.

6. The semiconductor device according to claim 1, further comprising pixels that are each structured by the light-receiving element and the reading circuit, the first light shield layer and the second light shield layer being formed to be divided into pixel units.

7. The semiconductor device according to claim 1, wherein the first light shield layer and the second light shield layer are formed to be clear of the light-receiving element.

8. The semiconductor device according to claim 1, wherein the first light shield layer and the second light shield layer are formed of a conductive metal or conductive metal compound.

9. An electronic device comprising:
the semiconductor device according to claim 1; and
a processing device that performs processing on charges read from the semiconductor device.
